(19) United States
(12) Patent Application Publication
(10) Pub. No.: US 2024/0352287 A1
(43) Pub. Date: Oct. 24, 2024

(54) CURABLE ADHESIVE COMPOSITION, FILMY ADHESIVE, METHOD FOR PRODUCING MULTILAYERED WIRING BOARD, AND MULTILAYERED WIRING BOARD

(71) Applicant: Resonac Corporation, Tokyo (JP)

(72) Inventors: Masashi OHKOSHI, Tokyo (JP); Nozomu TAKANO, Tokyo (JP); Kunihiko AKAI, Tokyo (JP); Hiroyuki IZAWA, Tokyo (JP); Yuka ITOH, Tokyo (JP); Shunsuke TAKAGI, Tokyo (JP)

(21) Appl. No.: 18/683,425

(22) PCT Filed: Aug. 10, 2022
(86) PCT No.: PCT/JP2022/030638

§ 371 Date: Jun. 18, 2024

(30) Foreign Application Priority Data
Aug. 20, 2021 (JP) 2021-135040

(51) Int. Cl. C09J 9/02; C09J 179/08; H05K 1/11; H05K 3/46

(52) U.S. Cl. CPC C09J 9/02; C09J 179/08; H05K 1/113; H05K 3/46; H05K 2201/032; H05K 2201/0338; H05K 2203/0278; H05K 2203/1105

(57) ABSTRACT

A curable adhesive composition used for bonding a wiring member constituting a multilayered wiring board, in which the curable adhesive composition satisfies all the following conditions (A) and (B) when a thermal expansion coefficient and a glass transition temperature of a cured product are designated as CTE₀ (ppm/° C.) and Tg₀ (° C.), respectively:

$$( A ) 5 \leq {CTE}_{0} \leq 270 \\ ( B ) 140 \leq {Tg}_{0} \leq 280$$

### TECHNICAL FIELD

The present disclosure relates to a curable adhesive composition, a filmy adhesive, a method for producing a multilayered wiring board, and a multilayered wiring board.

### BACKGROUND ART

A multilayered wiring board has a configuration in which a plurality of insulating layers such as insulating substrates are laminated, and a wiring pattern produced by a conductor is formed on one or both surfaces of each insulating layer. Wiring patterns between different insulating layers are connected by a conductive through holes, conductive pillars, or the like penetrating one or more insulating layers in a thickness direction (see, for example, Patent Literature 1 below). Furthermore, a multilayered wiring board may have a connection structure in which conductive through holes or conductive pillars are connected by a bonding material such as solder via an electrode provided as necessary (see, for example, Patent Literature 2 below).

### CITATION LIST

### Patent Literature

Patent Literature 1: Japanese Unexamined Patent Publication No. 2013-211518

Patent Literature 2: Japanese Unexamined Patent Publication No. 2003-218542

### SUMMARY OF INVENTION

### Technical Problem

Processes such as production of conductive through holes or conductive pillars and solder reflow are factors that increase a process time, energy cost, or environmental load in the production of a multilayered wiring board, and there is a demand for simplification of a production process. On the other hand, a multilayered wiring board used in a semiconductor package or the like is required to ensure reliability, such as sufficient connectivity under high-temperature and high-humidity conditions.

The present disclosure has been made in view of the above circumstances, and an object thereof is to provide a method for producing a multilayered wiring board capable of simplifying a production process while ensuring connectivity of a multilayered wiring board under high-temperature and high-humidity conditions, and a curable adhesive composition and a filmy adhesive which can be used in this method. Furthermore, another object of the present disclosure is to provide a multilayered wiring board.

### Solution to Problem

As aspect of the present disclosure provides a method for producing a multilayered wiring board, the method including a step of heating and pressurizing a first wiring member having a first electrode portion on a surface thereof, a second wiring member having a second electrode portion on a surface thereof, and a filmy adhesive containing conductive particles and a curable adhesive composition in a state where the first electrode portion and the second electrode portion are disposed to face each other with the filmy adhesive interposed therebetween, to electrically connect the first electrode portion and the second electrode portion, in which when a thermal expansion coefficient and a glass transition temperature of a cured product of the curable adhesive composition are designated as CTE₀ (ppm/° C.) and Tg₀ (° C.), respectively, the following conditions (A) and (B) are all satisfied:

$$( A ) 5 \leq {CTE}_{0} \leq 270 \\ ( B ) 140 \leq {Tg}_{0} \leq 280$$

According to the above-described method, the wiring members can be connected to each other in a short time, at low energy cost, and with a low environmental load, for example, by a step of laminating and pressing the first wiring member, the filmy adhesive, and the second wiring member, or the like, and further, connectivity or the like of a multilayered wiring board under high-temperature and high-humidity conditions can be sufficiently ensured by satisfying all the above-described conditions (A) and (B). Furthermore, in the production of a multilayered wiring board, the above-described step is included one or more times, so that the production process can be simplified.

Furthermore, another aspect of the present disclosure provides a curable adhesive composition used for bonding a wiring member constituting a multilayered wiring board, in which when a thermal expansion coefficient and a glass transition temperature of a cured product of the curable adhesive composition are designated as CTE₀ (ppm/° C.) and Tg₀ (° C.), respectively, the following conditions (A) and (B) are all satisfied:

$$( A ) 5 \leq {CTE}_{0} \leq 270 \\ ( B ) 140 \leq {Tg}_{0} \leq 280$$

Further, still another aspect of the present disclosure provides a filmy adhesive containing the above-described curable adhesive composition and conductive particles.

Still another aspect of the present disclosure provides a multilayered wiring board including a first wiring member having a first electrode portion, a second wiring member having a second electrode portion, and a connection portion containing conductive particles electrically connecting the first electrode portion and the second electrode portion and a resin cured product bonding the first wiring member and the second wiring member, the connection portion being provided between the first wiring member and the second wiring member, in which when a thermal expansion coefficient and a glass transition temperature of the resin cured product are designated as CTE₀ (ppm/° C.) and Tg₀ (° C.), respectively, the following conditions (A) and (B) are all satisfied:

$$( A ) 5 \leq {CTE}_{0} \leq 270 \\ ( B ) 140 \leq {Tg}_{0} \leq 280$$

Still another aspect of the present disclosure provides an electronic component including the aforementioned multilayered wiring board.

### Advantageous Effects of Invention

According to the present disclosure, it is possible to provide a method for producing a multilayered wiring board capable of simplifying a production process while ensuring connectivity or the like of a multilayered wiring board under high-temperature and high-humidity conditions, and an adhesive composition and a filmy adhesive which can be used in this method. Furthermore, according to the present disclosure, it is possible to provide a multilayered wiring board.

### BRIEF DESCRIPTION OF DRAWINGS

FIG. 1 is a schematic cross-sectional view illustrating an embodiment of a filmy adhesive.

FIG. 2 is a schematic cross-sectional view for describing an example of a method for producing a multilayered wiring board.

FIG. 3 is a schematic cross-sectional view for describing an example of the method for producing a multilayered wiring board.

FIG. 4 is a schematic cross-sectional view illustrating an embodiment of a multilayered wiring board.

### DESCRIPTION OF EMBODIMENTS

Hereinafter, modes for carrying out the present disclosure will be described in detail with reference to the drawings in some cases. However, the present disclosure is not limited to the following embodiments. Note that, in the present specification, “(meth)acrylic acid” means acrylic acid or methacrylic acid, and “(meth)acrylate” means acrylate or methacrylate corresponding thereto. “A or B” may include either one of A and B, and may also include both of A and B.

Furthermore, in the present specification, the term “step” includes not only an independent step but also a step by which an intended action of the step is achieved, even though the step cannot be clearly distinguished from other steps. Furthermore, a numerical range that has been indicated by use of “to” indicates the range that includes the numerical values which are described before and after “to”, as the minimum value and the maximum value, respectively.

Further, in the present specification, when a plurality of substances corresponding to each component exist in the composition, the content of each component in the composition means the total amount of the plurality of substances that exist in the composition, unless otherwise specified. Furthermore, listed materials may be used singly or in combinations of two or more kinds, unless otherwise specified.

Furthermore, in the numerical ranges that are described stepwise in the present specification, the upper limit value or the lower limit value of the numerical range of a certain stage may be replaced with the upper limit value or the lower limit value of the numerical range of another stage. Furthermore, in a numerical range described in the present specification, the upper limit value or the lower limit value of the numerical range may be replaced with a value shown in the Examples.

### Curable Adhesive Composition

A curable adhesive composition of the present embodiment may be a thermosetting resin composition containing a thermosetting resin, and as necessary, a curing agent or a curing accelerator.

Examples of the thermosetting resin include an epoxy resin, a polyimide resin, a triazine resin, a phenolic resin, a melamine resin, and modified products of these resins.

As the epoxy resin, a bisphenol type epoxy resin, a novolac type epoxy resin, an aliphatic chain epoxy resin, epoxidized polybutadiene, a glycidyl ester type epoxy resin, a glycidyl amine type epoxy resin, and the like can be used, and bisphenol type epoxy resins such as a bisphenol A type epoxy resin, a bisphenol F type epoxy resin, and a bisphenol S type epoxy resin, or novolac type epoxy resins such as a cresol novolac type epoxy resin, a bisphenol A novolac type epoxy resin, and a salicylaldehyde phenol novolac type epoxy resin may be used. From the viewpoint of improving heat resistance, a bisphenol A novolac type epoxy resin, a cresol novolac type epoxy resin, or a salicylaldehyde phenol novolac type epoxy resin can be used.

The thermosetting resin may be used singly, or can also be used in combination of two or more kinds thereof.

The content of the thermosetting resin in the curable adhesive composition may be 10 to 90% by mass, may be 20 to 80% by mass, and may be 30 to 70% by mass, based on the total mass of the curable adhesive composition.

As the curing agent, various conventionally known ones can be used, and for example, in the case of using an epoxy resin as a resin, polyfunctional phenols such as dicyandiamide, diaminodiphenylmethane, diaminodiphenyl sulfone, phthalic anhydride, pyromellitic anhydride, phenol novolac, and cresol novolac, and the like can be used.

The curing agent may be used singly, or can also be used in combination of two or more kinds thereof.

The content of the curing agent in the curable adhesive composition may be 10 to 90 parts by mass, may be 20 to 80 parts by mass, and may be 30 to 70 parts by mass, with respect to 100 parts by mass of the thermosetting resin.

Examples of the curing accelerator include an imidazole-based compound, an organic phosphorus-based compound, a tertiary amine, and a quaternary ammonium salt.

The curing accelerator may be used singly, or can also be used in combination of two or more kinds thereof.

The content of the curing accelerator in the curable adhesive composition may be 0.01 to 10 parts by mass, may be 0.05 to 8 parts by mass, and may be 0.1 to 5 parts by mass, with respect to 100 parts by mass of the thermosetting resin.

The curable resin composition of the present embodiment can contain a phenolic resin having a hydroxyl equivalent of 300 g/eq or less for the purpose of improving the heat resistance of a cured product. As such a phenolic resin, novolac type phenolic resins such as phenol novolac, cresol novolac, bisphenol A novolac, bisphenol F novolac, and catechol novolac, and those in which the aromatic ring of these resins is substituted with an alkyl group can be used. The hydroxyl equivalent of the phenolic resin may be 250 g/eq or less from the viewpoint of improving the heat resistance of a cured product, and may be 50 g/eq or more and may be 100 g/eq or more from the viewpoint of handleability and favorable reactivity.

Note that, the hydroxyl equivalent of the phenolic resin is determined by the following measurement method.

### Measurement Method of Hydroxyl Equivalent

In a round-bottomed flask, 1 g of a sample is accurately weighed and placed, and further, 5 mL of acetic anhydride and pyridine test solution is accurately weighed and placed. Next, an air cooler is attached to the flask and the flask is heated at 100° C. for 1 hour. After cooling the flask, 1 mL of water is added, and the flask is heated at 100° C. for 10 minutes again. After cooling the flask again, the air cooler and the neck of the flask are washed with 5 mL of neutralized methanol, and then 1 mL of phenolphthalein reagent is added thereto. The solution obtained in this way is titrated using a 0.1 mol/L potassium hydroxide-ethanol solution to determine a hydroxyl value. From the obtained hydroxyl value, a hydroxyl equivalent (g/eq) in terms of mass per 1 mol (1 eq) of hydroxyl group is calculated.

The content of the phenolic resin in the curable resin composition can be set so that the number of hydroxyl groups of the phenolic resin is 0.5 to 2 per one epoxy group of the epoxy resin.

Furthermore, the curable resin composition of the present embodiment may contain a modified polymaleimide compound (M) having a structural unit derived from a polymaleimide compound (m1) (hereinafter, sometimes referred to as “component (m1)”) and a structural unit derived from an amine compound (m2) (hereinafter, sometimes referred to as “component (m2)”) having an amino group, for the purpose of improving the heat resistance of a cured product.

Examples of the component (m1) include N,N′-ethylenebismaleimide, N,N′-hexamethylenebismaleimide, N,N′-(1,3-phenylene) bismaleimide, N,N′-[1,3-(2-methylphenylene)]bismaleimide, N,N′-[1,3-(4-methylphenylene)]bismaleimide, N,N′-(1,4-phenylene) bismaleimide, bis(4-maleimide phenyl)methane, bis(3-methyl-4-maleimide phenyl)methane, 3,3-dimethyl-5,5-diethyl-4,4-diphenylmethane bismaleimide, bis(4-maleimide phenyl)ether, bis(4-maleimide phenyl)sulfone, bis(4-maleimide phenyl)sulfide, bis(4-maleimide phenyl) ketone, bis(4-maleimide cyclohexyl)methane, 1,4-bis(4-maleimide phenyl)cyclohexane, 1,4-bis(maleimide methyl)cyclohexane, 1,4-bis(maleimide methyl)benzene, 1,3-bis(4-maleimidephenoxy)benzene, 1,3-bis(3-maleimidephenoxy)benzene, bis[4-(3-maleimidephenoxy)phenyl]methane, bis[4-(4-maleimidephenoxy)phenyl]methane, 1,1-bis[4-(3-maleimidephenoxy)phenyl]ethane, 1,1-bis[4-(4- maleimidephenoxy)phenyl]ethane, 1,2-bis[4-(3-maleimidephenoxy)phenyl]ethane, 1,2-bis[4-(4-maleimidephenoxy)phenyl]ethane, 2,2-bis[4-(3-maleimidephenoxy) phenyl] propane, 2,2-bis[4-(4-maleimidephenoxy)phenyl]propane, 2,2-bis[4-(3-maleimidephenoxy)phenyl]butane, 2,2-bis[4-(4-maleimidephenoxy)phenyl]butane, 2,2-bis[4-(3-maleimidephenoxy)phenyl]-1,1,1,3,3,3-hexafluoropropane, 2,2-bis[4-(4-maleimidephenoxy)phenyl]-1,1,1,3,3,3-hexafluoropropane, 4,4-bis(3- maleimidephenoxy)biphenyl, 4,4-bis(4-maleimidephenoxy)biphenyl, bis[4-(3-maleimidephenoxy)phenyl]ketone, bis[4-(4-maleimidephenoxy)phenyl]ketone, 2,2-bis(4-maleimide phenyl) disulfide, bis(4-maleimide phenyl)disulfide, bis[4-(3-maleimidephenoxy)phenyl]sulfide, bis[4-(4-maleimidephenoxy)phenyl]sulfide, bis[4-(3-maleimidephenoxy)phenyl]sulfoxide, bis[4-(4-maleimidephenoxy)phenyl]sulfoxide, bis[4-(3-maleimidephenoxy)phenyl]sulfone, bis[4-(4-maleimidephenoxy)phenyl]sulfone, bis[4-(3-maleimidephenoxy) phenyl]ether, bis[4-(4-maleimidephenoxy)phenyl]ether, 1,4-bis[4-(4-maleimidephenoxy)-α,α-dimethylbenzyl]benzene, 1,3-bis[4-(4-maleimidephenoxy)-α,α-dimethylbenzyl]benzene, 1,4-bis[4-(3-maleimidephenoxy)-α,α-1,3-bis[4-(3-maleimidephenoxy)-α,α-dimethylbenzyl]benzene, dimethylbenzyl]benzene, 1,4-bis[4-(4-maleimidephenoxy)-3,5-dimethyl-α,α-dimethylbenzyl]benzene, 1,3-bis[4-(4-maleimidephenoxy)-3,5-dimethyl-α,α-dimethylbenzyl]benzene, 1,4-bis[4-(3-maleimidephenoxy)-3,5-dimethyl-x,xx-dimethylbenzyl]benzene, 1,3-bis[4-(3-maleimidephenoxy)-3,5-dimethyl-cx,cx-dimethylbenzyl]benzene, and polyphenylmethane maleimide (for example, trade name: BMI-2300 or the like manufactured by Daiwa Fine Chemicals Co., Ltd.). The maleimide compound may be used singly or in combination of two or more kinds thereof.

The component (m2) is preferably an amine compound (polyamine compound) having at least two amino groups, and may be a diamine compound having two amino groups. Examples of the component (m2) include aromatic diamine compounds such as 4,4′-diaminodiphenylmethane, 4,4′-diamino-3,3′-dimethyldiphenylmethane, 3,3′-diethyl-4,4′-diaminodiphenylmethane, 4,4′-diaminodiphenylether, 4,4′-diaminodiphenylsulfone, 3,3′-diaminodiphenylsulfone, 4,4′-diaminodiphenylketone, 4,4′-diaminobiphenyl, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl)propane, 3,3′-dimethyl-5,5′-diethyl-4,4′-diaminodiphenylmethane, 2,2-bis(4-aminophenyl) propane, 2,2-bis[4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 1,3-bis[1-[4-(4-aminophenoxy)phenyl]-1-methylethyl]benzene, 1,4-bis[1-[4-(4-aminophenoxy)phenyl]-1-methylethyl]benzene, 4,4′-[1,3-phenylenebis(1-methylethylidene)] bisaniline, 4,4′-[1,4-phenylenebis(1-methylethylidene)]bisaniline, 3,3′-[1,3-phenylenebis(1-methylethylidene)]bisaniline, bis[4-(4-aminophenoxy)phenyl]sulfone, bis[4-(3-aminophenoxy)phenyl]sulfone, and 9,9-bis(4-aminophenyl) fluorene; and amine compounds having a siloxane skeleton.

The modified polymaleimide compound (M) may be a compound including a structure represented by the following Formula (1), which is formed by an addition reaction between the maleimide group of the component (m1) and the amino group of the component (m2). Note that, in Formula (1), * indicates a bonding position.

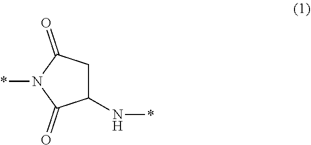 [SMILES: *NC1CC(=O)N(*)C1=O]

The content of the structural unit derived from the component (ml) in the modified polymaleimide compound (M) is not particularly limited, and may be 50 to 95% by mass, may be 70 to 92% by mass, and may be 75 to 90% by mass.

The content of the structural unit derived from the component (m2) in the modified polymaleimide compound (M) is not particularly limited, and may be 5 to 50% by mass, may be 8 to 30% by mass, and may be 10 to 25% by mass.

The total content of the structural unit derived from the component (m1) and the structural unit derived from the component (m2) in the modified polymaleimide compound (M) is not particularly limited, and may be 80% by mass or more, may be 90% by mass or more, may be 95% by mass or more, and may be 100% by mass (that is, the modified polymaleimide compound (M) is composed of only the structural unit derived from the component (m1) and the structural unit derived from the component (m2)).

The content of the modified polymaleimide compound in the curable resin composition may be 5 to 90% by mass, may be 10 to 80% by mass, may be 20 to 70% by mass, may be 30 to 70% by mass, and may be 40 to 70% by mass, based on the total mass of the curable adhesive composition.

Furthermore, the curable resin composition of the present embodiment may contain a radical polymerizable compound. As the radical polymerizable compound, a compound having a radically polymerizable functional group can be used. Examples of the radically polymerizable functional group include a vinyl group, an acryloyl group, and a methacryloyl group.

The curable resin composition of the present embodiment can be optionally used together with an inorganic filler. Examples of the inorganic filler include silica, alumina, talc, mica, kaolin, aluminum hydroxide, boehmite, magnesium hydroxide, zinc borate, zinc stannate, zinc oxide, titanium oxide, boron nitride, calcium carbonate, barium sulfate, aluminum borate, potassium titanate, and glass powder and hollow glass beads of E-glass, T-glass, D-glass, and the like. These may be used singly or as a mixture of two or more kinds thereof.

Of the above-described inorganic fillers, from the viewpoint of dielectric characteristics, heat resistance, and low thermal expansion properties, silica can be used. Examples of silica include precipitated silica with a high water content, which is produced by a wet process; and dry process silica with substantially no bonding water, which is prepared by a dry process, and examples of the dry process silica further include crushed silica, fumed silica, and fused spherical silica that are generated based on the difference in the production methods. Among these, from the viewpoint of low thermal expansion properties and high fluidity when silica is filled into a resin, fused spherical silica can be used.

The average particle size of the inorganic filler may be 0.1 to 10 μm, and may be 0.3 to 8 μm. By setting the average particle size of the inorganic filler to 0.1 μm or more, fluidity when silica is highly filled in the resin can be maintained favorably, and by setting the average particle size thereof to 10 μm or less, the probability of incorporating coarse particles is reduced so that occurrence of failures caused by coarse particles can be suppressed. Here, the average particle size is a particle size indicated by the point corresponding to exactly 50% of the volume of particles determined from a cumulative distribution curve of particle size, in which the total volume of particles is defined as 100%, and can be measured by particle size distribution analyzer adopting a laser diffraction scattering method, or the like.

The inorganic filler may be used singly, or can also be used in combination of two or more kinds thereof.

The content of the inorganic filler in the curable adhesive composition may be 0 to 90% by mass, may be 0 to 80% by mass, and may be 0 to 70% by mass, based on the total mass of the curable adhesive composition.

The curable adhesive composition of the present embodiment can optionally contain known thermoplastic resins, elastomers, organic fillers, flame retardants, ultraviolet absorbers, antioxidants, photopolymerization initiators, fluorescent brighteners, adhesion improvers, and the like.

When a thermal expansion coefficient and a glass transition temperature of a cured product of the curable adhesive composition are designated as CTE₀ (ppm/° C.) and Tg₀ (° C.), respectively, the curable adhesive composition of the present embodiment may satisfy all the following conditions (A) and (B):

$$( A ) 5 \leq {CTE}_{0} \leq 270 \\ ( B ) 140 \leq {Tg}_{0} \leq 90$$

In the present specification, the thermal expansion coefficient of the cured product (or the resin cured product) of the curable adhesive composition is determined by thermomechanical analysis using a thermomechanical analyzer by a compaction method under the following conditions.

### [Thermal Expansion Coefficient]

An evaluation substrate composed of the cured product of the curable adhesive composition and having a thickness of 250 μm±50 μm and a size of 5 mm square is produced. The evaluation substrate is mounted in the X direction on a TMA test device (TMA2940 manufactured by Du Pont), and then measurement is continuously performed twice under the measurement conditions of a load of 5 g and a temperature increase rate of 10° C./min. The average thermal expansion coefficient from 30 to 100° C. in the second measurement is calculated, and this is regarded as a thermal expansion coefficient value.

The thermal expansion coefficient of the cured product (or the resin cured product) of the curable adhesive composition determined above can also be said to be the thermal expansion coefficient in the thickness direction of the cured product.

In the present specification, the glass transition temperature of the cured product (or the resin cured product) of the curable adhesive composition is determined by thermomechanical analysis using a thermomechanical analyzer by a compaction method under the following conditions.

### [Glass Transition Temperature]

An evaluation substrate composed of the cured product of the curable adhesive composition and having a thickness of 250 μm±50 μm and a size of 5 mm square is produced. The evaluation substrate is mounted in the Z direction on a TMA test device (TMA2940 manufactured by Du Pont), and then measurement is continuously performed twice under the measurement conditions of a load of 5 g and a temperature increase rate of 10° C./min. The temperature indicated at the intersection point of tangents at two points of the inflection point ±30° C. of the thermal expansion curve in the second measurement is regarded as a glass transition temperature.

Note that, in the case of determining the thermal expansion coefficient or the glass transition temperature of the cured product of the curable adhesive composition, ten films having a thickness of 25 μm obtained by forming the curable adhesive composition into a film shape are laminated, and this laminate is cured under the conditions of 150 to 250° C. for 30 to 120 minutes, so that an evaluation substrate composed of the cured product of the curable adhesive composition having a reaction rate of 90% or more can be produced. The reaction rate is determined according to the following method. A part of the curable adhesive composition is scraped off to obtain two 5 mg evaluation samples before curing. Next, one of the evaluation samples before curing is heated at 150 to 250° C. for 30 to 120 minutes to obtain an evaluation sample after heating. For each of the evaluation sample before heating and the evaluation sample after heating, a DSC exothermic calorific value is measured using a differential scanning calorimetry (DSC) device (product name DSC7 manufactured by PerkinElmer Inc.) in a nitrogen flow in a measurement temperature range of 30 to 250° C. and at a temperature increase rate of 10° C./min. The reaction rate is determined based on the measured DSC exothermic calorific value from the following formula.

$$Reaction rate = ( Cx - Cy ) \times 100 / Cx$$

[in the formula, Cx represents the DSC exothermic calorific value (J/g) of the evaluation sample before heating, and Cy represents the DSC exothermic calorific value (J/g) of the evaluation sample after heating.]

In the present specification, the resin cured product may contain a component other than a resin component, such as an inorganic filler.

Furthermore, the cured product of the curable adhesive composition and the resin cured product may have insulating properties.

From the viewpoint of connectivity or the like under high-temperature and high-humidity conditions, CTE₀ (ppm/° C.) may be 5 or more, may be 10 or more, may be 30 or more, may be 50 or more, and 70 or more. From the viewpoint of suppressing warpage of the substrate, CTE₀ (ppm/° C.) may be 270 or less, may be 250 or less, may be 230 or less, may be 200 or less, may be 180 or less, may be 100 or less, and may be 50 or less. From these viewpoints, CTE₀ (ppm/° C.) may be 5 to 270, may be 5 to 250, may be 5 to 100, and may be 5 to 50.

To reduce CTEo, CTE₀ can be adjusted, for example, by adjusting the blended amount of the inorganic filler, blending a plurality of kinds of the inorganic filler, selecting a thermosetting resin or curing agent having a rigid skeleton such as an aromatic ring, or combining these means.

From the viewpoint of connectivity or the like under high-temperature and high-humidity conditions, Tg₀ (° C.) may be 140 or more, may be 150 or more, and may be 180 or more. Tg₀ (C) may be 280 or less, may be 250 or less, may be 230 or less, and may be 200 or less.

From these viewpoints, Tg₀ (° C.) may be 140 to 280, and may be 150 to 280.

To increase Tgo, Tg₀ can be adjusted, for example, by selecting a thermosetting resin or curing agent having a rigid skeleton, increasing the cross-linking density of the cured product, selecting an inorganic filler having high heat resistance, increasing the blended amount of the inorganic filler, or combining these means.

The curable adhesive composition of the present embodiment is used for bonding a wiring member constituting a multilayered wiring board, and particularly, can be used in combination with the conductive particles and applied to connection between the wiring members.

### Filmy Adhesive

A filmy adhesive of the present embodiment contains the aforementioned curable adhesive composition of the present embodiment and conductive particles. The filmy adhesive may have a configuration including a layer composed of the curable adhesive composition and conductive particles dispersed and existing in this layer.

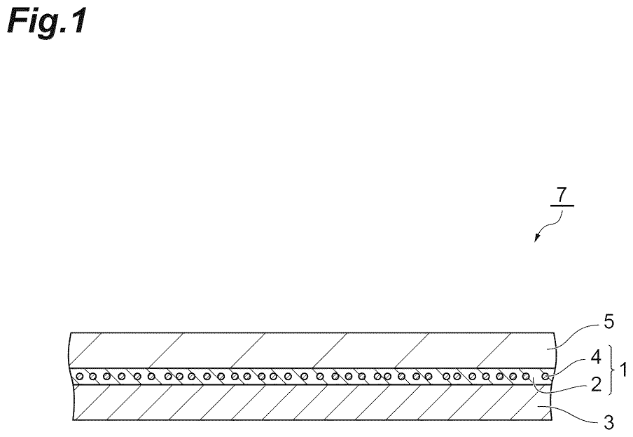

FIG. 1 is a schematic cross-sectional view illustrating an embodiment of an adhesive film including the filmy adhesive of the present embodiment. An adhesive film 7 illustrated in FIG. 1 includes a carrier film 3, a filmy adhesiveb 1 provided on the carrier film 3, and a release film 5 provided on a side of the filmy adhesive 1 opposite to the carrier film 3 side. The filmy adhesive 1 contains a curable adhesive composition layer 2 composed of the aforementioned curable adhesive composition of the present embodiment and conductive particles 4 dispersed and existing in this layer.

The conductive particles may be metal particles of Au, Ag, Ni, Cu, solder, or the like, conductive carbon particles configured by conductive carbon, and the like. Furthermore, the conductive particles may be obtained by covering the surface of a transition metal such as Ni with a noble metal such as Au. From the viewpoint of obtaining sufficient pot life, the surface layer can be made of a noble metal such as Au, Ag, or a platinum group metal, and may be made of Au.

Furthermore, the conductive particles may be coated conductive particles in which a conductive layer is formed on a non-conductive particle surface by a method such as coating the surfaces of non-conductive particles made of glass, ceramic, plastic or the like with the aforementioned conductive substance, and an outermost layer configured by a noble metal is further provided. In the case of using such particles or heat-fusible metal particles, these particles have deformability by hot pressing, so that the contact area between the wiring member and the electrode portion during connection can increase to improve reliability.

The conductive particles may be insulating coated conductive particles each including the metal particles, the conductive carbon particles, or the coated conductive particles described above and an insulating material such as a resin and provided with an insulating layer which covers the surface of the particles. When the conductive particles are insulating coated conductive particles, even in a case where the content of the conductive particles is large, the surface of the particles is coated with the resin, so that occurrence of a short circuit due to contact between the conductive particles can be suppressed.

As the conductive particles, one kind of the various conductive particles mentioned above is used singly or two or more kinds thereof are used in combination.

The maximum particle size of the conductive particles needs to be smaller than the minimum interval between the electrode portions of the wiring members (the shortest distance between adjacent electrode portions). The maximum particle size of the conductive particles may be 1.0 μm or more, may be 2.0 μm or more, and may be 2.5 μm or more, from the viewpoint of excellent dispersibility and electrical conductivity. The maximum particle size of the conductive particles may be 50 μm or less, may be 30 μm or less, and may be 20 μm or less, from the viewpoint of excellent dispersibility and electrical conductivity. From these viewpoints, the maximum particle size of the conductive particles may be 1.0 to 50 μm, may be 2.0 to 30 μm, and may be 2.5 to 20 μm. In the present specification, the particle sizes of arbitrary 300 (pcs) conductive particles are measured by observation using a scanning electron microscope (SEM), and the largest value thus obtained is regarded as the maximum particle size of the conductive particles. Note that, in a case where the conductive particles are not spherical, for example, the conductive particles have protrusions, the particle size of the conductive particle is the diameter of a circle circumscribing the conductive particle in an image of an SEM.

The average particle size of the conductive particles may be 1.0 um or more, may be 2.0 μm or more, and may be 2.5 μm or more, from the viewpoint of excellent dispersibility and electrical conductivity. The average particle size of the conductive particles may be 50 μm or less, may be 30 μm or less, and may be 20 μm or less, from the viewpoint of excellent dispersibility and electrical conductivity. From these viewpoints, the average particle size of the conductive particles may be 1.0 to 50 μm, may be 2.0 to 30 μm, and may be 2.5 to 20 μm. In the present specification, the particle sizes of arbitrary 300 (pcs) conductive particles are measured by observation using a scanning electron microscope (SEM), and the average value of particle sizes thus obtained is regarded as the average particle size.

The conductive particles may have high dispersibility in the filmy adhesive. For example, when a state where adjacent particles are not in contact with each other is kept, stable connection characteristics can be obtained. Furthermore, when the distance between the particles is equal, there is a tendency that the connection between the upper and lower electrode portions are more stable. Further, the conductive particles may be in a state of being aligned in a plane direction.

The particle density of the conductive particles in the filmy adhesive may be 10 particles/mm² or more, 100 particles/mm² or more, 1000 particles/mm² or more, or 5000 particles/mm² or more, from the viewpoint of obtaining stable connection characteristics. The particle density of the conductive particles in the filmy adhesive may be 100000 particles/mm² or less, 70000 particles/mm² or less, 50000 particles/mm² or less, or 30000 particles/mm² or less, from the viewpoint of improving insulating properties between adjacent electrode portions or wirings.

The content of the conductive particles in the filmy adhesive may be 0 to 90 parts by mass, may be 1 to 85 parts by mass, and may be 2 to 80 parts by mass, with respect to 100 parts by mass of the curable adhesive composition.

The thickness of the filmy adhesive may be 1 to 200 μm, may be 3 to 150 μm, and may be 5 to 100 μm.

According to the filmy adhesive of the present embodiment, the wiring members can be connected to each other in a short time, at low energy cost, and with a low environmental load, for example, by a step of laminating and pressing the first wiring member, the filmy adhesive, and the second wiring member, or the like, and further, the curable adhesive composition satisfies all the above-described conditions (A) and (B) so that connectivity or the like of a multilayered wiring board under high-temperature and high-humidity conditions can be sufficiently ensured. Furthermore, in the production of a multilayered wiring board, the above-described step is included one or more times, so that the production process can be simplified.

The filmy adhesive of the present embodiment can be produced by the following method. Specifically, first, a component constituting the curable adhesive composition and conductive particles are added into a solvent (organic solvent) and dissolved or dispersed by stirring/mixing, kneading, and the like to prepare a varnish composition (varnish-like curable adhesive composition). Thereafter, a varnish composition is applied onto a release-treated substrate (such as a carrier film or a release film) by using a knife coater, a roll coater, an applicator, a comma coater, a die coater, or the like, and heated to volatilize the solvent, so that a filmy adhesive can be formed on the substrate.

As the solvent used for preparing the varnish composition, a solvent having a property capable of uniformly dissolving or dispersing each component may be used. Examples of such a solvent include toluene, acetone, methyl ethyl ketone, methyl isobutyl ketone, ethyl acetate, propyl acetate, butyl acetate, and cyclohexanone. These solvents can be used singly or in combinations of two or more kinds thereof. In preparation of the varnish composition, stirring/mixing and kneading can be performed, for example, by using a stirrer, a mortar machine, a triple roll mill, a ball mill, a bead mill, or a homo-disper.

The substrate is not particularly limited as long as it has heat resistance to withstand the heating conditions when the solvent is volatilized, and examples thereof include substrates (for example, films) composed of oriented polypropylene (OPP), polyethylene terephthalate (PET), polyethylene naphthalate, polyethylene isophthalate, polybutylene terephthalate, polyolefin, polyacetate, polycarbonate, polyphenylene sulfide, polyamide, polyimide, cellulose, an ethylene-vinyl acetate copolymer, polyvinyl chloride, polyvinylidene chloride, a synthetic rubber system, a liquid crystal polymer, a fluororesin, and a metal foil of copper, aluminum, and the like.

The carrier film 3 is not particularly limited, and a polyethylene terephthalate film, a fluororesin film, a polyimide film, an oriented polypropylene film, a copper foil, or the like can be used. The release film 5 is not particularly limited, and a polyethylene terephthalate film, a fluororesin film, a polyimide film, an oriented polypropylene film, a copper foil, or the like can be used.

The heating conditions when the solvent is volatilized from the varnish composition applied to the substrate may be conditions under which the solvent is sufficiently volatilized. The heating conditions may be, for example, 40° C. or higher and 180° C. or lower for 0.1 minutes or longer and 20 minutes or shorter.

In the filmy adhesive of the present embodiment, a part of the solvent may remain without being removed. The content of the solvent in the filmy adhesive of the present embodiment may be, for example, 10% by mass or less, may be 5% by mass or less, and may be 1% by mass or less, based on the total mass of the filmy adhesive.

### Method for Producing Multilayered Wiring Board

Next, a method for producing a multilayered wiring board will be described.

A method for producing a multilayered wiring board of the present embodiment includes a step of heating and pressurizing a first wiring member having a first electrode portion on a surface thereof, a second wiring member having a second electrode portion on a surface thereof, and a filmy adhesive containing conductive particles and a curable adhesive composition in a state where the first electrode portion and the second electrode portion are disposed to face each other with the filmy adhesive interposed therebetween, to electrically connect the first electrode portion and the second electrode portion.

Note that, in the present specification, the wiring member means a member for configuring or forming a multilayered wiring board.

In a first embodiment, the filmy adhesive may be the aforementioned filmy adhesive of the present embodiment. That is, the thermal expansion coefficient and the glass transition temperature of a cured product of the curable adhesive composition may satisfy the conditions of CTE₀ (ppm/° C.) and Tg₀ (° C.) mentioned above.

In a second embodiment, in the above-described step, the first wiring member may include a first insulating portion containing a first resin cured product or a precursor thereof, the second wiring member may include a second insulating portion containing a second resin cured product or a precursor thereof, and when a thermal expansion coefficient and a glass transition temperature of the first insulating portion are designated as CTE₁ (ppm/° C.) and Tg₁ (° C.), respectively, a thermal expansion coefficient and a glass transition temperature of the second insulating portion are designated as CTE₂ (ppm/° C.) and Tg₂ (° C.), respectively, and a thermal expansion coefficient and a glass transition temperature of the cured product of the curable adhesive composition are designated as CTE₀ (ppm/° C.) and Tg₀ (° C.), respectively, the following conditions (1) to (4) may be all satisfied, the following conditions (5) to (8) may be all satisfied, the following conditions (1) to (8) may be all satisfied, the following conditions (1) to (2) and (9) to (10) may be all satisfied, and the following conditions (1) to (2) and (5) to (10) may be all satisfied.

$$( 1 ) 0 \leq \vert ( {CTE}_{1} - {CTE}_{0} ) / {CTE}_{1} \vert \leq 55 \\ ( 2 ) 0 \leq \vert ( {CTE}_{2} - {CTE}_{0} ) / {CTE}_{2} \vert \leq 55 \\ ( 3 ) 0 \leq \vert ( {Tg}_{1} - {Tg}_{0} ) / {Tg}_{1} \vert \leq 1.5 \\ ( 4 ) 0 \leq \vert ( {Tg}_{2} - {Tg}_{0} ) / {Tg}_{2} \vert \leq 1.5 \\ ( 5 ) 0 \leq \vert {CTE}_{1} - {CTE}_{0} \vert \leq 270 \\ ( 6 ) 0 \leq \vert {CTE}_{2} - {CTE}_{0} \vert \leq 270 \\ ( 7 ) 0 \leq \vert {Tg}_{1} - {Tg}_{0} \vert \leq 150 \\ ( 8 ) 0 \leq \vert {Tg}_{2} - {Tg}_{0} \vert \leq 150 \\ ( 9 ) 0 \leq \vert ( {Tg}_{1} - {Tg}_{0} ) / {Tg}_{0} \vert \leq 1.5 \\ ( 10 ) 0 \leq \vert ( {Tg}_{2} - {Tg}_{0} ) / {Tg}_{0} \vert \leq 1.5$$

CTE₀ and Tg₀ have the same meanings as in the curable adhesive composition mentioned above.

In the present specification, the thermal expansion coefficient of the insulating portion in the wiring member is determined by thermomechanical analysis using a thermomechanical analyzer by a compaction method under the following conditions.

### [Thermal Expansion Coefficient]

An evaluation substrate composed of the material constituting the insulating portion and having a thickness of 250 μm±50 μm and a size of 5 mm square is produced. The evaluation substrate is mounted in the X direction on a TMA test device (TMA2940 manufactured by Du Pont), and then measurement is continuously performed twice under the measurement conditions of a load of 5 g and a temperature increase rate of 10° C./min. The average thermal expansion coefficient from 30 to 100° C. in the second measurement is calculated, and this is regarded as a thermal expansion coefficient value.

Note that, in a case where the insulating portion contains a precursor of the resin cured product, the thermal expansion coefficient of the insulating portion means the thermal expansion coefficient of the insulating portion after the precursor is cured.

Furthermore, the thermal expansion coefficient of the insulating portion determined above can also be said to be the thermal expansion coefficient in the thickness direction of the insulating portion (or the lamination direction of the wiring member).

In the present specification, the glass transition temperature of the insulating portion in the wiring member is determined by thermomechanical analysis using a thermomechanical analyzer by a compaction method under the following conditions.

### [Glass Transition Temperature]

An evaluation substrate composed of the material constituting the insulating portion and having a thickness of 250 μm±50 μm and a size of 5 mm square is produced. The evaluation substrate is mounted in the Z direction on a TMA test device (TMA2940 manufactured by Du Pont), and then measurement is continuously performed twice under the measurement conditions of a load of 5 g and a temperature increase rate of 10° C./min. The temperature indicated at the intersection point of tangents at two points of the inflection point ±30° C. of the thermal expansion curve in the second measurement is regarded as a glass transition temperature.

Note that, in a case where the insulating portion contains a precursor of the resin cured product, the glass transition temperature of the insulating portion means the glass transition temperature of the insulating portion after the precursor is cured.

The first and second insulating portions may contain a fiber substrate such as glass fiber, and also in this case, the above-described conditions (1) to (4) may be all satisfied, the above-described conditions (5) to (8) may be all satisfied, the above-described conditions (1) to (8) may be all satisfied, the above-described conditions (1) to (2) and (9) to (10) may be all satisfied, and the above-described conditions (1) to (2) and (5) to (10) may be all satisfied.

From the viewpoint of the connectivity or the like of the multilayered wiring board under high-temperature and high-humidity conditions, |(CTE₁−CTE₀)/CTE₁| and |(CTE₂−CTE₆)/CTE₂| each may be 53 or less, may be 4 or less, and may be 3 or less. Furthermore, from the same viewpoint, |CTE₁−CTE₀| and |CTE₂−CTE₀| each may be 260 or less, may be 250 or less, may be 230 or less, may be 200 or less, may be 40 or less, and may be 20 or less.

From the viewpoint of the connectivity or the like of the multilayered wiring board under high-temperature and high-humidity conditions, |(Tg₁−Tg₀)/Tg₁| and |(Tg₂−Tg)/Tg₂| each may be 1.2 or less, and may be 0.4 or less. Furthermore, from the same viewpoint, |Tg₁−Tg₀| and |Tg₂−Tg₀| each may be 130 or less, may be 120 or less, and may be 100 or less.

From the viewpoint of the connectivity or the like of the multilayered wiring board under high-temperature and high-humidity conditions, |(Tg₁−Tg₀)/Tg₀ and |(Tg₂−Tg₀)/Tg₁| each may be 1.2 or less, and may be 0.6 or less.

Examples of the first wiring member include a multilayered substrate, a core substrate, a coreless multilayered board, a flexible multilayered board, a buildup multilayered board, and a multilayered redistribution layer.

Examples of the second wiring member include a multilayered substrate, a core substrate, a coreless multilayered board, a flexible multilayered board, a buildup multilayered board, and a multilayered redistribution layer.

Examples of combinations of the first wiring member and the second wiring member include a core substrate and a buildup multilayered board, a core substrate and a flexible multilayered board, and a core substrate and coreless multilayered board.

The first electrode portion and the second electrode portion are not particularly limited, but may be a pillar electrode, a bump electrode, a solder bump, or the like provided on the surface of the wiring member, and may be a part of a wiring, a part of a conductive pillar, or a part of a conductive through hole.

The material of the electrode is not particularly limited, and examples thereof include copper, tin, gold, and solder. The material of the wiring is not particularly limited, and copper is generally exemplified. The material of the conductive pillar is not particularly limited, and copper, gold, solder, and the like are generally exemplified. The material of the conductive through hole is not particularly limited, and copper plating, various conductive pastes, and the like are generally exemplified.

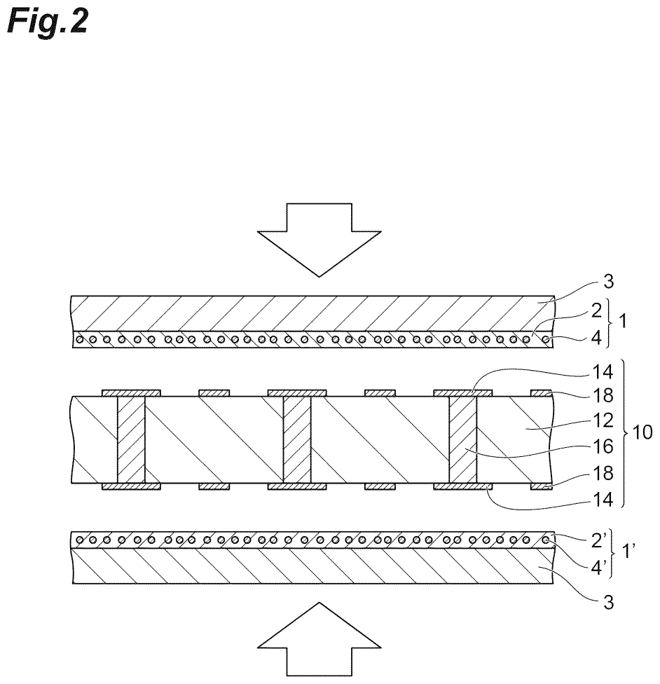

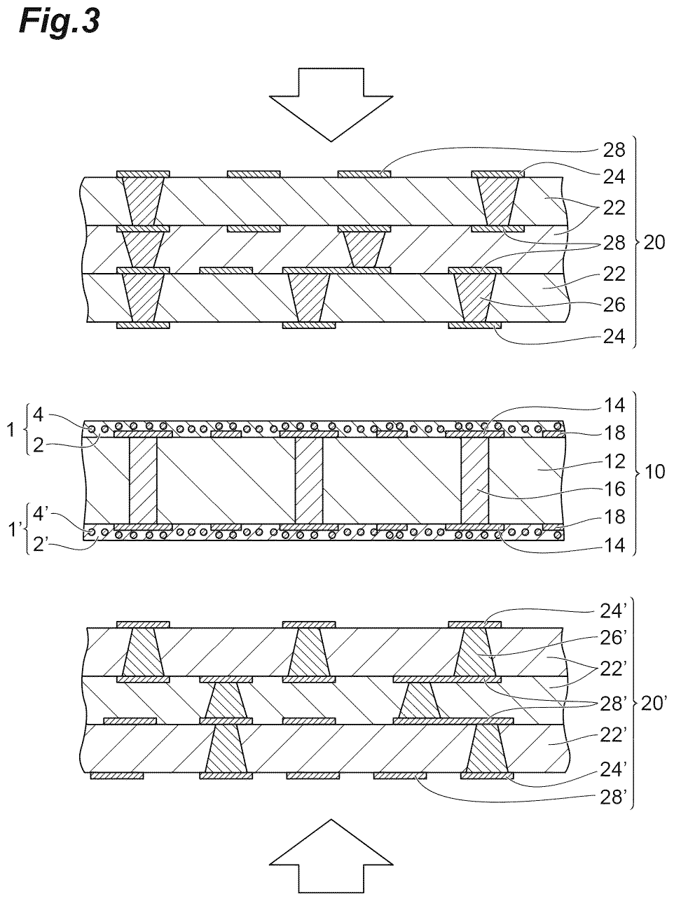

FIG. 2 and FIG. 3 are schematic cross-sectional views illustrating examples of the method for producing a multilayered wiring board. In this method, Step S1 of preparing the adhesive film 7 illustrated in FIG. 1, Step S2 of laminating the filmy adhesives 1 and 1; of the adhesive film 7 on both main surfaces of the first wiring member 10 having first electrode portions 14 on surfaces thereof, and Step S3 of overlapping a second wiring member 20 having a second electrode portion 24 on a surface thereof, a first wiring member 10 having filmy adhesives 1 and 1′ laminated thereon, and a third wiring member 10′ having a third electrode portion 16′ on a surface thereof in this order so that the first electrode portion 14 faces the second electrode portion 24 and the first electrode portion 14 faces the third electrode portion 24′, and heating and pressurizing these members in this state are provided.

The first wiring member 10 is a core substrate and has a first insulating portion 12 composed of a resin cured product, first electrode portions 14, a conductive pillar 16 connecting these electrode portions, and wirings 18 formed on the first insulating portion 12.

The second wiring member 20 and the third wiring member 20′ are build-up layers and has, in addition to the electrode portions 24 and 24′, a plurality of insulating portions 22 and 22′ each composed of a resin cured product, wirings 28 and 28′ provided on the insulating portion and between the insulating portions, and vias 26 and 26′ connecting the different wirings 28 and 28′ to each other.

In Step S1, the filmy adhesives 1 and 1′ may be the aforementioned filmy adhesive of the present embodiment. That is, the thermal expansion coefficient and the glass transition temperature of a cured product of the curable adhesive composition may satisfy the conditions of CTE₀ (ppm/° C.) and Tg₀ (° C.) mentioned above.

In Step b 2, after the release film 5 is peeled off from the adhesive film 7, the filmy adhesives 1 and 1′ can be laminated on both main surfaces of the first wiring member 10.

Examples of the lamination method include heating and pressing roll lamination, vacuum lamination, and heating platen press. The lamination temperature may be 30 to 200° C.

In this step, the filmy adhesive is laminated on the first wiring member, but the filmy adhesive may be laminated on the second wiring member.

In Step S3, heating and pressurizing can be performed, for example, by a method such as heating platen press, heating and pressing roll lamination, and vacuum pressure lamination.

The pressure may be 0.1 to 50 MPa, and may be 0.2 to 40 MPa. The heating temperature may be 40 to 280° C., and may be 50 to 260° C. These pressurization and heating can be performed for 1 to 7200 seconds, and can be performed for 1 to 3600 seconds.

Furthermore, in the step illustrated in FIG. 3, when a thermal expansion coefficient and a glass transition temperature of the insulating portion 12 are designated as CTE₁ (ppm/° C.) and Tg₁ (° C.), respectively, a thermal expansion coefficient and a glass transition temperature of the insulating portion 22 (or the insulating portion 22′) are designated as CTE₂ (ppm/° C.) and Tg₂ (° C.), respectively, and a thermal expansion coefficient and a glass transition temperature of a cured product of the curable adhesive composition 1 (or the curable adhesive compositio 1′) are designated as CTE₀ (ppm/° C.) and Tg₀ (° C.), respectively, the aforementioned conditions (1) to (4) may be satisfied, and the aforementioned conditions (1) to (2) and (9) to (10) may be satisfied.

From the viewpoint of the connectivity or the like of the multilayered wiring board under high-temperature and high-humidity conditions, |(CTE₁−CTE₆)/CTE₁| and |(CTE₂−CTE₀)/CTE₂| each may be 53 or less, may be 4 or less, and may be 3 or less. Furthermore, from the same viewpoint, |CTE₁−CTE₀| and |CTE₂−CTE₀| each may be 260 or less, may be 250 or less, may be 230 or less, may be 200 or less, may be 40 or less, and may be 20 or less.

From the viewpoint of the connectivity or the like of the multilayered wiring board under high-temperature and high-humidity conditions, |(Tg₁−Tg₀)/Tg₁| and |(Tg₂−Tg₀)/Tg₂| each may be 1.2 or less, and may be 0.4 or less. Furthermore, from the same viewpoint, |Tg₁−Tg₀| and |Tg₂−Tg₀ each may be 130 or less, may be 120 or less, and may be 100 or less.

From the viewpoint of the connectivity or the like of the multilayered wiring board under high-temperature and high-humidity conditions, |(Tg₁−Tg₀)/Tg₀| and |(Tg₂−Tg₀)/Tg₀| each may be 1.2 or less, and may be 0.6 or less.

In a case where the wiring member has the plurality of insulating portions 22 and 22′ like the second wiring member 20 and the third wiring member 20′, and the physical properties of the respective insulating portions are different, an average value of the thermal expansion coefficients of all the insulating portions in the wiring member may satisfy the same conditions as the aforementioned conditions (1) and (2), and/or (5) and (6) (that is, CTE and CTE₂ are respectively replaced with an average value), and the thermal expansion coefficient of the insulating portion closest to the filmy adhesive may satisfy the aforementioned conditions (1) and (2), and/or (5) and (6).

Similarly, an average value of the glass transition temperatures of all the insulating portions in the wiring member may satisfy the same conditions as the aforementioned conditions (3) and (4), and/or (7) and (8) (that is, Tg₁ and Tg₂ are respectively replaced with an average value), and the glass transition temperature of the insulating portion closest to the filmy adhesive may satisfy the aforementioned conditions (3) and (4), and/or (7) and (8).

Similarly, an average value of the glass transition temperatures of all the insulating portions in the wiring member may satisfy the same conditions as the aforementioned conditions (9) and (10), and/or (7) and (8) (that is, Tg₁ and Tg₂ are respectively replaced with an average value), and the glass transition temperature of the insulating portion closest to the filmy adhesive may satisfy the aforementioned conditions (9) and (10), and/or (7) and (8).

### Multilayered Wiring Board

A multilayered wiring board of the present embodiment includes a first wiring member having a first electrode portion, a second wiring member having a second electrode portion, and a connection portion containing conductive particles electrically connecting the first electrode portion and the second electrode portion and a resin cured product bonding the first wiring member and the second wiring member, the connection portion being provided between the first wiring member and the second wiring member.

In a first embodiment, the multilayered wiring board may satisfy all the following conditions (A) and (B) when a thermal expansion coefficient and a glass transition temperature of the resin cured product are designated as CTE₀ (ppm/° C.) and Tg₀ (° C.), respectively:

$$( A ) 5 \leq {CTE}_{0} \leq 270 \\ ( B ) 140 \leq {Tg}_{0} \leq 280$$

From the viewpoint of connectivity or the like under high-temperature and high-humidity conditions, CTE₀ may be 5 to 270 ppm/° C., may be 5 to 250 ppm/° C., may be 5 to 100 ppm/° C., and may be 5 to 50 ppm/° C.

From the viewpoint of connectivity or the like under high-temperature and high-humidity conditions, Tg₀ may be 140 to 280° C., and may be 150 to 280° C.

In a second embodiment, in the multilayered wiring board, the first wiring member may include a first insulating portion containing a first resin cured product, the second wiring member may include a second insulating portion containing a second resin cured product, and when a thermal expansion coefficient and a glass transition temperature of the first insulating portion are designated as CTE₁ (ppm/° C.) and Tg₁ (° C.), respectively, a thermal expansion coefficient and a glass transition temperature of the second insulating portion are designated as CTE₂ (ppm/° C.) and Tg₂ (° C.), respectively, and a thermal expansion coefficient and a glass transition temperature of the resin cured product are designated as CTE₀ (ppm/° C.) and Tg₀ (° C.), respectively, the following conditions (1) to (4) may be all satisfied, the following conditions (5) to (8) may be all satisfied, the following conditions (1) to (8) may be all satisfied, the following conditions (1) to (2) and (9) to (10) may be all satisfied, and the following conditions (1) to (2) and (5) to (10) may be all satisfied.

$$( 1 ) 0 \leq \vert ( {CTE}_{1} - {CTE}_{0} ) / {CTE}_{1} \vert \leq 55 \\ ( 2 ) 0 \leq \vert ( {CTE}_{2} - {CTE}_{0} ) / {CTE}_{2} \vert \leq 55 \\ ( 3 ) 0 \leq \vert ( {Tg}_{1} - {Tg}_{0} ) / {Tg}_{1} \vert \leq 1.5 \\ ( 4 ) 0 \leq \vert ( {Tg}_{2} - {Tg}_{0} ) / {Tg}_{2} \vert \leq 1.5 \\ ( 5 ) 0 \leq \vert {CTE}_{1} - {CTE}_{0} \vert \leq 270 \\ ( 6 ) 0 \leq \vert {CTE}_{2} - {CTE}_{0} \vert \leq 270 \\ ( 7 ) 0 \leq \vert {Tg}_{1} - {Tg}_{0} \vert \leq 150 \\ ( 8 ) 0 \leq \vert {Tg}_{2} - {Tg}_{0} \vert \leq 150 \\ ( 9 ) 0 \leq \vert ( {Tg}_{1} - {Tg}_{0} ) / {Tg}_{0} \vert \leq 1.5 \\ ( 10 ) 0 \leq \vert ( {Tg}_{2} - {Tg}_{0} ) / {Tg}_{0} \vert \leq 1.5$$

CTE₀ and Tg₀ have the same meanings as in the curable adhesive composition mentioned above, and may satisfy the same conditions. Furthermore, CTE_{1,} CTE₂, Tg₁, and Tg₂ have the same meanings as in the method for producing a multilayered wiring board mentioned above, and may satisfy the same conditions.

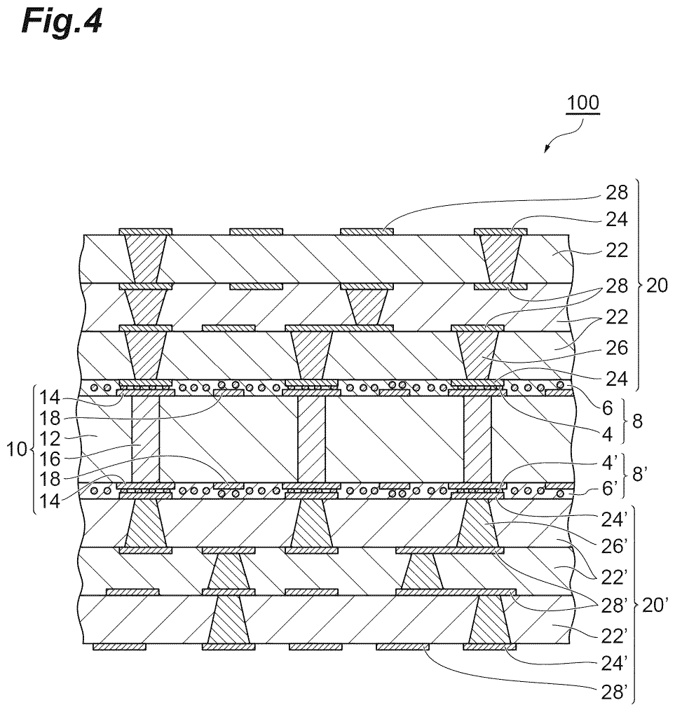

FIG. 4 is a schematic cross-sectional view illustrating an embodiment of a multilayered wiring board. A multilayered wiring board 100 illustrated in FIG. 4 includes a first wiring member 10 having a first electrode portion 14, a second wiring member 20 having a second electrode portion 24, a third wiring member 20′ having a third electrode portion 24′, a connection portion 8 containing conductive particles 4 electrically connecting the first electrode portion 14 and the second electrode portion 24 and a resin cured product 6 bonding the first wiring member 10 and the second wiring member 20, the connection portion 8 being provided between the first wiring member 10 and the second wiring member 20, and a connection portion 8′ containing conductive particles 4′ electrically connecting the first electrode portion 14 and the third electrode portion 24′ and a resin cured product 6′ bonding the first wiring member 10 and the third wiring member 20′, the connection portion 8′ being provided between the first wiring member 10 and the third wiring member 20′.

The multilayered wiring board 100 can be obtained by the methods illustrated in FIG. 2 and FIG. 3, and as the first, second, and third wiring members, the same as those described above are exemplified. The connection portions 8 and 8′ can be formed using the filmy adhesive of the present embodiment.

The multilayered wiring board illustrated in FIG. 4 may satisfy the aforementioned conditions of CTE₀ (ppm/° C.) and Tg₀ (° C.) when a thermal expansion coefficient and a glass transition temperature of the resin cured product 6 (or the resin cured product 6′) are designated as CTE₀ (ppm/° C.) and Tg₀ (° C.), respectively.

Furthermore, in the multilayered wiring board illustrated in FIG. 4, when a thermal expansion coefficient and a glass transition temperature of the insulating portion 12 are designated as CTE₁ (ppm/° C.) and Tg₁ (° C.), respectively, a thermal expansion coefficient and a glass transition temperature of the insulating portion 22 (or the insulating portion 22′) are designated as CTE₂ (ppm/° C.) and Tg₂ (° C.), respectively, and a thermal expansion coefficient and a glass transition temperature of the resin cured product 6 (or the resin cured product 6′) are designated as CTE₀ (ppm/° C.) and Tg₀ (° C.), respectively, the aforementioned conditions (1) to (4) may be satisfied, the aforementioned conditions (5) to (8) may be all satisfied, the aforementioned conditions (1) to (8) may be all satisfied, the aforementioned conditions (1) to (2) and (9) to (10) may be all satisfied, and the aforementioned conditions (1) to (2) and (5) to (10) may be all satisfied.

In a case where the wiring member has the plurality of insulating portions 22 and 22′ like the second wiring member 20 and the third wiring member 20′, and the physical properties of the respective insulating portions are different, an average value of the thermal expansion coefficients of all the insulating portions in the wiring member may satisfy the same conditions as the aforementioned conditions (1) and (2), and/or (5) and (6) (that is, CTE) and CTE₂ are respectively replaced with an average value), and the thermal expansion coefficient of the insulating portion closest to the filmy adhesive may satisfy the aforementioned conditions (1) and (2), and/or (5) and (6).

Similarly, an average value of the glass transition temperatures of all the insulating portions in the wiring member may satisfy the same conditions as the aforementioned conditions (3) and (4), and/or (7) and (8) (that is, Tg₁ and Tg₂ are respectively replaced with an average value), and the glass transition temperature of the insulating portion closest to the filmy adhesive may satisfy the aforementioned conditions (3) and (4), and/or (7) and (8).

Similarly, an average value of the glass transition temperatures of all the insulating portions in the wiring member may satisfy the same conditions as the aforementioned conditions (9) and (10), and/or (7) and (8) (that is, Tg₁ and Tg₂ are respectively replaced with an average value), and the glass transition temperature of the insulating portion closest to the filmy adhesive may satisfy the aforementioned conditions (9) and (10), and/or (7) and (8).

### Electronic Component

An electronic component of the present embodiment includes the aforementioned multilayered wiring board of the present embodiment. The electronic component of the present embodiment may have a member for forming an electronic component and the multilayered wiring board of the present embodiment. Examples of the member for forming an electronic component include a semiconductor chip and a capacitor.

Specific examples of the electronic component include a semiconductor device and a semiconductor package.

### EXAMPLES

### Synthesis of Modified Polymaleimide Compound

### Synthesis Example 1

In a heating-cooling reaction container with a volume of 2 L equipped with a moisture determination device including a thermometer, a stirrer, and a reflux cooling tube, 100 g of both-end diamine-modified siloxane (manufactured by Shin-Etsu Chemical Co., Ltd., trade name: X-22-161A, functional group equivalent of amino group: 800 g/mol), 450 g of 2,2-bis[4-(4-maleimidephenoxy)phenyl]propane, and 550 g of propylene glycol monomethyl ether were placed, and the mixture was reacted at 120° C. for 3 hours, thereby obtaining a solution containing a modified polymaleimide compound. The weight average molecular weight (Mw) of the obtained modified maleimide resin was 2500.

### Synthesis of Polyurethane Acrylate (UAI)

### Synthesis Example 2

To a reaction container equipped with a stirrer, a thermometer, a reflux cooling tube having a calcium carbonate drying tube, and a nitrogen gas introduction tube, 2500 parts by mass (2.50 mol) of poly (l,6-hexanediol carbonate) (trade name: Duranol T5652, manufactured by Asahi Chemical Industry Co., Ltd., number average molecular weight: 1000) and 666 parts by mass (3.00 mol) of isophorone diisocyanate (manufactured by Sigma-Aldrich) were uniformly added dropwise over 3 hours. Next, nitrogen gas was sufficiently introduced into the reaction container, and then the inside of the reaction container was heated to 70 to 75° C. to cause a reaction. Then, 0.53 parts by mass (4.3 mmol) of hydroquinone monomethyl ether (manufactured by Sigma-Aldrich) and 5.53 parts by mass (8.8 mmol) of dibutyltin dilaurate (manufactured by Sigma-Aldrich) were added to the reaction container, and then 238 parts by mass (2.05 mol) of 2-hydroxyethyl acrylate (manufactured by Sigma-Aldrich) was added thereto, and the mixture was reacted at 70° C. for 6 hours in an air atmosphere. Thereby, polyurethane acrylate (UA1) was obtained. The weight average molecular weight of the polyurethane acrylate (UA1) was 15000. Note that, the weight average molecular weight was measured by gel permeation chromatography (GPC) and using a calibration curve obtained by standard polystyrene according to the following conditions.

### Measurement Conditions

Apparatus: GPC-8020 manufactured by Tosoh Corporation
Detector: RI-8020 manufactured by Tosoh Corporation
Column: Gelpack GLA160S+GLA150S manufactured by
Hitachi Chemical Co., Ltd.
Sample concentration: 120 mg/3 mL
Solvent: tetrahydrofuran
Injection amount: 60 μL
Pressure: 2.94×10⁶ Pa (30 kgf/cm²)
Flow rate: 1.00 mL/min

### Synthesis of Polyester Urethane Resin

### Synthesis Example 3

Into a stainless steel autoclave with a heater equipped with a stirrer, a thermometer, a condenser, a vacuum generator, and a nitrogen gas introduction tube, 48 parts by mass of isophthalic acid and 37 parts by mass of neopentyl glycol were charged, and 0.02 parts by mass of tetrabutoxy titanate as a catalyst was further charged. Next, the mixture was heated to 220° C. in a nitrogen flow and stirred for 8 hours as it was. Thereafter, the pressure was reduced to atmospheric pressure (760 mmHg) to cool the mixture to room temperature. Thereby, a white precipitate was precipitated. Next, the white precipitate was taken out, washed with water, and vacuum-dried to obtain a polyester polyol. After sufficiently drying the obtained polyester polyol, the dried polyester polyol was dissolved in MEK (methyl ethyl ketone), and charged into a four-neck flask equipped with a stirrer, a dropping funnel, a reflux condenser, and a nitrogen gas introduction tube. Furthermore, dibutyltin dilaurate as a catalyst was charged in an amount of 0.05 parts by mass with respect to 100 parts by mass of the polyester polyol, 4,4′-diphenylmethane diisocyanate was dissolved in an amount of 50 parts by mass with respect to 100 parts by mass of the polyester polyol in MEK and then charged with a dropping funnel, and the mixture was stirred at 80° C. for 4 hours to a desired polyester urethane resin.

### Production of Conductive Particles

### Production Example 1

Gold plating (the outermost layer is a gold layer) was formed on the surface of polystyrene particles to obtain conductive particles having an average particle size of 20 μm.

### Production of Filmy Adhesive

### Example 1

14.61 g of “NC-7000L” (naphthol aralkyl cresol copolymer-type epoxy resin, manufactured by Nippon Kayaku Co., Ltd., trade name, epoxy equivalent: 230 g/eq), 40.90 g of the modified polymaleimide compound of Synthesis Example 1, 0.17 g of “G-8009L” (isocyanate-masked imidazole, manufactured by DKS Co. Ltd., trade name), and 0.080 g of “YOSHINOX BB” (phenol derivative, manufactured by Mitsubishi Chemical Corporation, trade name) were dissolved in 25.8 g of methyl ethyl ketone (MEK), and then 5.60 g of the conductive particles of Production Example 1 was added thereto, thereby preparing a varnish composition.

The varnish composition was applied onto a release-treated substrate (PET film having a thickness of 50 μm) by using a coating device, and then dried with hot air at 70° C. for 3 minutes to volatilize the solvent, thereby forming a filmy adhesive having a thickness of 25 μm on the substrate.

### Example 2

23.12 g of “NC-3000H” (biphenyl novolac type epoxy resin, manufactured by Nippon Kayaku Co., Ltd., trade name, epoxy equivalent: 289 g/eq), 9.52 g of “KA-1165” (cresol novolac type phenolic resin, manufactured by DIC Corporation, trade name, hydroxyl equivalent: 119 g/eq), and 0.103 g of “G-8009L” (isocyanate-masked imidazole, DKS Co. Ltd., trade name) were dissolved in 9.86 g of methyl ethyl ketone (MEK), and then 10.77 g of “SC-2050 (KC)” (fused spherical silica, average particle size: 0.5 μm, manufactured by ADMATECHS COMPANY LIMITED, trade name) and 8.44 g of the conductive particles of Production Example 1 were added thereto, thereby preparing a varnish composition.

The varnish composition was applied onto a release-treated substrate (PET film having a thickness of 50 μm) by using a coating device, and then dried with hot air at 70° C. for 3 minutes to volatilize the solvent, thereby forming a filmy adhesive having a thickness of 25 μm on the substrate.

### Comparative Example 1

40 g of the polyester urethane resin of Synthesis Example 3, 34 g of the polyurethane acrylate (UA1) of Synthesis Example 2, 3 g of “Light Ester P-2M” (2-methacryloyloxyethyl acid phosphate, manufactured by Kyoeisha Chemical Co., Ltd., trade name), 8 g of “NYPER BMT-K40” (benzoyl peroxide, manufactured by NOF CORPORATION, trade name), and 5 g of “M-315” (isocyanuric acid EO-modified triacrylate, manufactured by TOAGOSEI CO., LTD., trade name) were dissolved in 9.86 g of methyl ethyl ketone (MEK), and then 10 g of “R104” (silica fine particles, average particle size (primary particle size): 12 nm, manufactured by NIPPON AEROSIL CO., LTD., trade name) and 8.44 g of the conductive particles of Production Example 1 were added thereto, thereby preparing a varnish composition.

The varnish composition was applied onto a release-treated substrate (PET film having a thickness of 50 μm) by using a coating device, and then dried with hot air at 70° C. for 3 minutes to volatilize the solvent, thereby forming a filmy adhesive having a thickness of 25 μm on the substrate.

### Comparative Example 2

25.0 g of “PKHC” (phenoxy resin, manufactured by Union Carbide Corporation, trade name), 10.0 g of a resin in which acrylic rubber fine particles are dispersed in a bisphenol A type epoxy resin (content of acrylic fine particles: 17% by mass, epoxy equivalent: 220 to 240), 10.0 g of a cresol novolac type epoxy resin (epoxy equivalent: 163 to 175), and 55.0 g of the following curing agent A were dissolved in 60.0 g of toluene, and then 10.0 g of “KMP-605” (silica fine particles, average particle size: 2 μm, manufactured by Shin-Etsu Chemical Co., Ltd., trade name) and 10.0 g of the conductive particles of Production Example 1 were added thereto, thereby preparing a varnish composition. Curing agent A: master batch-type curing agent (manufactured by Asahi Kasei Corporation) obtained by dispersing a microcapsule type curing agent with an average particle size of 5 μm having an imidazole modified substance as core whose surface is coated with polyurethane, in a liquid bisphenol F type epoxy resin

The varnish composition was applied onto a release-treated substrate (PET film having a thickness of 50 μm) by using a coating device, and then dried with hot air at 70° C. for 3 minutes to volatilize the solvent, thereby forming a filmy adhesive having a thickness of 25 μm on the substrate.

### Comparative Example 3

23.12 g of “NC-3000H” (biphenyl novolac type epoxy resin, manufactured by Nippon Kayaku Co., Ltd., trade name, epoxy equivalent: 289 g/eq), 9.36 g of “KA-1160” (cresol novolac type phenolic resin, manufactured by DIC Corporation, trade name, hydroxyl equivalent: 117 g/eq), and 0.103 g of “G-8009L” (isocyanate-masked imidazole, DKS Co. Ltd., trade name) were dissolved in 9.79 g of methyl ethyl ketone (MEK), and then 10.72 g of “SC-2050 (KC)” (fused spherical silica, average particle size: 0.5 μm, manufactured by ADMATECHS COMPANY LIMITED, trade name) and 8.40 g of the conductive particles of Production Example 1 were added thereto, thereby preparing a varnish composition.

The varnish composition was applied onto a release-treated substrate (PET film having a thickness of 50 μm) by using a coating device, and then dried with hot air at 70° C. for 3 minutes to volatilize the solvent, thereby forming a filmy adhesive having a thickness of 25 μm on the substrate.

### Evaluation of Filmy Adhesive

For the filmy adhesives obtained in Examples and Comparative Examples, the thermal expansion coefficient and the glass transition temperature of the cured product were measured by the following methods.

### [Production of Sample for Evaluation]

Ten filmy adhesives were laminated and cured under the following conditions to produce a sample for evaluation composed of the cured product of the filmy adhesive having a reaction rate of 90% or more and having a thickness of 250 μm and a size of 5 mm square.
Example 1: at 240° C. for 120 minutes
Example 2: at 180° C. for 60 minutes
Comparative Example 1: at 180° C. for 30 minutes
Comparative Example 2: at 180° C. for 30 minutes
Comparative Example 3; at 180° C. for 60 minutes

### [Measurement of Thermal Expansion Coefficient]

The sample for evaluation was mounted in the X direction on a TMA test device (TMA2940 manufactured by Du Pont), and then the linear thermal expansion curve at 25 to 260° C. was continuously measured twice under the measurement conditions of a load of 5 g and a temperature increase rate of 10° C./min. The average thermal expansion coefficient from 30° to 100° C. in the second measurement was calculated, and this was regarded as a thermal expansion coefficient value.

### [Measurement of Glass Transition Temperature]

The sample for evaluation was mounted in the Z direction on a TMA test device (TMA2940 manufactured by Du Pont), and then the thermal expansion curve at 25 to 260° C. was continuously measured twice under the measurement conditions of a load of 5 g and a temperature increase rate of 10° C./min. The temperature indicated at the intersection point of tangents at two points of the inflection point ±30° C. of the thermal expansion curve in the second measurement was regarded as a glass transition temperature.

TABLE 1

| | | | Comparative | Comparative | Comparative |
|---|---|---|---|---|---|
| | Example 1 | Example 2 | Example 1 | Example 2 | Example 3 |
| Thermal expansion | 15 | 28 | 528 | 124 | 54 |
| coefficient (ppm/° C.) | | | | | |
| Glass transition | 252 | 170 | 50 | 102 | 136 |
| temperature (° C.) | | | | | |

According to the above-described filmy adhesives of Examples 1 and 2, the wiring members can be connected to each other in a short time, at low energy cost, and with a low environmental load, for example, by a step of laminating and pressing the first wiring member, the filmy adhesive, and the second wiring member, or the like, and further, connectivity or the like of a multilayered wiring board under high-temperature and high-humidity conditions can be expected to be sufficiently ensured by satisfying all the above-described conditions (A) and (B).

The above-described filmy adhesives of Examples 1 and 2 can satisfy all the above-described conditions (1) to (10), for example, in a case where the wiring members each including an insulating portion having a thermal expansion coefficient and a glass transition temperature of 8 to 10 ppm/° C. and 250 to 270° C., respectively, are connected to each other.

### REFERENCE SIGNS LIST

1, 1′: filmy adhesive, 2, 2′: curable resin composition layer, 3: carrier film, 4, 4′: conductive particle, 5: release film, 6, 6′: resin cured product, 7: adhesive film, 8, 8′: connection portion, 10: first wiring member, 12: first insulating portion, 14: first electrode portion, 16: conductive pillar, 18: wiring, 20: second wiring member, 20′: third wiring member, 22: second insulating portion, 22′: third insulating portion, 24: second electrode portion, 24′: third electrode portion, 26: via, 26′: via, 28, 28′: wiring, 100: multilayered wiring board.

1. A method for producing a multilayered wiring board, the method comprising:
a step of heating and pressurizing a first wiring member having a first electrode portion on a surface thereof, a second wiring member having a second electrode portion on a surface thereof, and a filmy adhesive containing conductive particles and a curable adhesive composition in a state where the first electrode portion and the second electrode portion are disposed to face each other with the filmy adhesive interposed therebetween, to electrically connect the first electrode portion and the second electrode portion, wherein
when a thermal expansion coefficient and a glass transition temperature of a cured product of the curable adhesive composition are designated as CTE₀ (ppm/° C.) and Tg₀ (° C.), respectively, the following conditions (A) and (B) are all satisfied:
$$( A ) 5 \leq {CTE}_{0} \leq 270 \\ ( B ) 140 \leq {Tg}_{0} \leq 280$$

2. A curable adhesive composition used for bonding a wiring member constituting a multilayered wiring board, wherein
when a thermal expansion coefficient and a glass transition temperature of a cured product of the curable adhesive composition are designated as CTE₀ (ppm/° C.) and Tg₀ (° C.), respectively, the following conditions (A) and (B) are all satisfied:
$$( A ) 5 \leq {CTE}_{0} \leq 270 \\ ( B ) 140 \leq {Tg}_{0} \leq 280$$

3. A filmy adhesive comprising the curable adhesive composition according to claim 2 and conductive particles.

4. A multilayered wiring board comprising:
a first wiring member having a first electrode portion;
a second wiring member having a second electrode portion; and
a connection portion containing conductive particles electrically connecting the first electrode portion and the second electrode portion and a resin cured product bonding the first wiring member and the second wiring member, the connection portion being provided between the first wiring member and the second wiring member, wherein
when a thermal expansion coefficient and a glass transition temperature of the resin cured product are designated as CTE₀ (ppm/° C.) and Tg₀ (° C.), respectively, the following conditions (A) and (B) are all satisfied:
$$( A ) 5 \leq {CTE}_{0} \leq 270 \\ ( B ) 140 \leq {Tg}_{0} \leq 280$$

5. 5An electronic component comprising the multilayered wiring board according to claim 4.
